(19) United States
(12) Patent Application Publication
(10) Pub. No.: US 2007/0190681 A1
(43) Pub. Date: Aug. 16, 2007

(54) Silicon-on-insulator near infrared active pixel sensor array

(75) Inventors: Jong-Jan Lee, Camas, WA (US); Jer-Shen Maa, Vancouver, WA (US); Douglas J. Tweet, Camas, WA (US); Sheng Teng Hsu, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/352,724

(22) Filed: Feb. 13, 2006

(51) Int. Cl. H01L 21/00

(52) U.S. Cl. 438/54; 257/E31.054

(57) ABSTRACT

A method is provided for forming a near infrared (NIR) active pixel sensor array on a silicon-on-insulator (SOI) substrate. The method forms a first wafer comprising a high resistance first Si substrate and a moderately doped first Si layer, and forms a second wafer comprising a first silicon oxide layer and a second Si layer. The method bonds the first wafer to the second wafer, forming a SOI substrate. Then, a diode is formed with a p-n junction space charge region extending into the first Si substrate. A thin-film transistor (TFT) is formed in the second Si layer, and interconnects are formed between the TFT and the diode. For example, first Si substrate may have a resistivity of greater than 100 ohm-cm, and the first Si layer may have a dopant concentration in the range of about 1×10¹⁶ to about 5×10¹⁸ cm⁻³.

### BACKGROUND OF THE INVENTION

1. Field of the Invention

This invention generally relates to integrated circuit (IC) fabrications and, more particularly, to a method for fabricating a near infrared active pixel sensor array formed on a silicon-on-insulator wafer.

2. Description of the Related Art

A photodiode is a p-n junction receptive to optical input. The depletion (or space charge) region at the junction interface has a high electric field and readily separates photogenerated electron hole pairs. Photodiodes can be either zero biased or reverse biased. At zero bias, light creates a current in the forward bias direction. This phenomena is called the photovoltaic effect. However, photodiodes are usually operated in the reverse biased condition. The reverse bias voltage creates a high electric field in the depletion region, reducing the carrier transit time and lowering the diode capacitance. A p-i-n photodiode is one type of p-n phtodiode whose depletion region depth into the intrinsic layer can be tailored to optimize quantum efficiency and frequency response.

There are many applications for photodetection in the near infrared region (the wavelength between 0.7 micron to 2 microns), such as in fiber-optical communication, security, and thermal imaging. Although III-V compound semiconductors provide superior optical performance over their silicon (Si)-based counterparts, the use of Si is desirable, as the compatibility of Si-based materials with conventional Si-IC technology promises the possibility of cheap, small, and highly integrated optical systems. Silicon photodiodes are widely used as photodetectors in the visible light wavelengths due to their low dark current and the above-mentioned compatibility with Si IC technologies.

Ge is a material with potential use in the fabrication of photo devices. Ge has a higher carrier mobility than Si, and is receptive to a different spectrum of light than Si. However, the interface between Ge and Si materials typically results in a large dark current, and therefore, is not suitable for high-density large-scale commercial applications. The leakage current is attributed to the poor Ge crystallinity at the Ge to silicon, or Ge to insulator interface.

Although both InGaAs and Ge detectors have strong photon absorption in the NIR wavelength range and so generate a high photocurrent, they have a high fabrication cost, and have a high dark current that generates noise. Therefore, there are only a limited number of products using InGaAs and Ge to detect NIR with wavelengths from 700 nanometers (nm) to 1100 nm.

Therefore, it is desirable that PN photodiodes be fabricated on Si wafers for the detection of NIR wavelengths between 700 nm and 1100 nm. The light penetration depths in Si are ˜10 micrometers (μm) and ˜100 μm for wavelengths of 800 nm and 1000 nm, respectively. Therefore, to make Si NIR detection effective, the space charge region (SCR) or the depletion region of the PN junction diode has to be deep. That is, the depth of the SCR should be 10 μm, or larger. For imager applications, every pixel of the image element contains a PN photodiode with several MOS transistors. For submicron CMOS technology, high doping in the MOS channel and small depletion in the source/drain regions are needed. Small depletion source/drain regions are contradictory to the requirement of a deep junction photodiode. Therefore, the absorption and efficiency of NIR light by a conventional Si CMOS imager is low. It is possible to adjust the PN diode and MOS transistor independently by fabricating the PN diode and MOS transistors in different regions of a substrate, but this design significantly increases the image pixel size.

Visible light CMOS imagers have been proposed for fabrication on silicon-on-insulator (SOI) wafers (C. Xu, W. Zhang, M. Chan, “A low voltage hybrid bulk/SOI CMOS active pixel image sensor,” IEEE Electron Device Letter, Vol. 22, No. 5, pp. 248-250 (2001). Xu describes MOS transistors fabricated on a thin Si surface layer, with photodiodes fabricated on a Si handle wafer. The MOS transistors and PN diode adjustments can be done independently and still maintain a small pixel size. Xu's Si substrate is p-type doped at a level of 10¹⁵ cm⁻³, which corresponds to a resistivity of ˜15 ohm-cm. The substrate resistivity implies that the depletion layer depth (thickness) is much less than 2 um, when reverse biased with about 3V, for use with the visible spectrum of light. Further, the depletion region extends to the Si/SiO2 interface of the SOI wafer, dramatically increasing the diode leakage current.

S. Seshadri, X. Zheng, B. Pain, and M. Wood, “Process and pixels for high performance imagers in SOI-CMOS technology,” presented at the IEEE CCD-AIS Workshop, 2003, also describe MOS transistors fabricated on a thin Si surface layer, with photodiodes fabricated on a Si handle wafer. Seshadri uses a higher resistance Si substrate (2000 ohm-cm) than Xu. High energy boron ion implantation (260 keV) converts the Si substrate surface to a dopant concentration of 5×10¹⁷ to 5×10¹⁸ cm⁻³. This surface p-layer reduces the diode leakage current.

It would be advantageous if SOI fabrication techniques could be used to build deep depletion region Si p-n diodes for use in NIR wavelength detection.

### SUMMARY OF THE INVENTION

This present invention describes a process for fabricating a low-cost device for NIR image detection, from a SOI wafer. The use of a SOI Imager to detect NIR wavelengths is especially useful in safety, security, and medical applications. A CMOS imager fabricated on SOI has a quantum efficiency in the NIR range that is 2× to 10× better than that fabricated on bulk Si wafers.

Accordingly, a method is provided for forming a near infrared (NIR) active pixel sensor array on a silicon-on-insulator (SOI) substrate. The method forms a first wafer comprising a high resistance first Si substrate and a moderately doped first Si layer, and forms a second wafer comprising a first silicon oxide layer and a second Si layer. The method bonds the first wafer to the second wafer, forming a SOI substrate. Then, a diode is formed with a p-n junction space charge region extending into the first Si substrate. A thin-film transistor (TFT) is formed in the second Si layer, and interconnects are formed between the TFT and the diode.

For example, the first Si substrate may have a resistivity of greater than 100 ohm-cm, and the first Si layer may have a dopant concentration in the range of about 1×10¹⁶ to about 5×10¹⁸ cm⁻³. In one aspect, the first wafer is formed by providing a high resistivity first Si substrate, and doping the first Si substrate to form the first Si layer with a thickness in the range of about 50 to 300 nanometers (nm).

More specifically, the first silicon oxide layer forms an island over the first Si layer with a first sidewall and an opposing second sidewall. The diode includes a first heavily doped region in the first Si layer adjacent the silicon oxide layer first sidewall, and a second heavily doped region, opposite in polarity to the first heavily doped region, in the first Si layer adjacent the silicon oxide layer second sidewall. In operation, the diode may be represented with two parallel space charge regions. A first space charge region extends into the first Si substrate at a depth greater than about 2 micrometers, in response to a reverse bias voltage of about 2 volts. A second space charge region extends through the first Si layer at a depth less than the first Si layer thickness, without intersecting the interface between the first Si layer and the first silicon oxide layer, in response to a reverse bias of about 5 volts. It is the first space charge region that is associated with the generation of photons in response to NIR wavelengths.

Additional details of the above-described method are provided below.

### BRIEF DESCRIPTION OF THE DRAWINGS

FIG. 1 is a partial cross-sectional view of a near infrared (NIR) active pixel sensor array on a silicon-on-insulator (SOI) substrate.

FIG. 2 is a partial cross-sectional view of a NIR active pixel sensor array on a SOI substrate with a p-doped Si substrate and a p-doped first Si layer.

FIG. 3 is a partial cross-sectional view of a NIR active pixel sensor array on a SOI substrate with a p-doped Si substrate and an n-doped first Si layer.

FIG. 4 is a partial cross-sectional view of a NIR active pixel sensor array on a SOI substrate with an n-doped Si substrate and an n-doped first Si layer.

FIG. 5 is a partial cross-sectional view of a NIR active pixel sensor array on a SOI substrate with an n-doped Si substrate and a p-doped first Si layer.

FIG. 6 is a partial cross-sectional view of a NIR active pixel sensor array of FIG. 2 depicting space charge regions.

FIGS. 7 through 10 are partial cross-sectional views showing steps in the fabrication of the NIR active pixel sensor array of FIG. 1.

FIG. 11 is a schematic block diagram showing an application for the NIR active pixel sensor array.

FIG. 12 is a graph depicting the difference in absorption spectra between normal and cancerous tissue.

FIG. 13 is a schematic diagram of a conventional active pixel circuit (prior art).

FIGS. 14A and 14B are flowcharts illustrating a method for forming a NIR active pixel sensor array on a SOI substrate.

FIG. 15 is a flowchart illustrating an alternate aspect to the method for forming a NIR active pixel sensor array on a SOI substrate.

### DETAILED DESCRIPTION

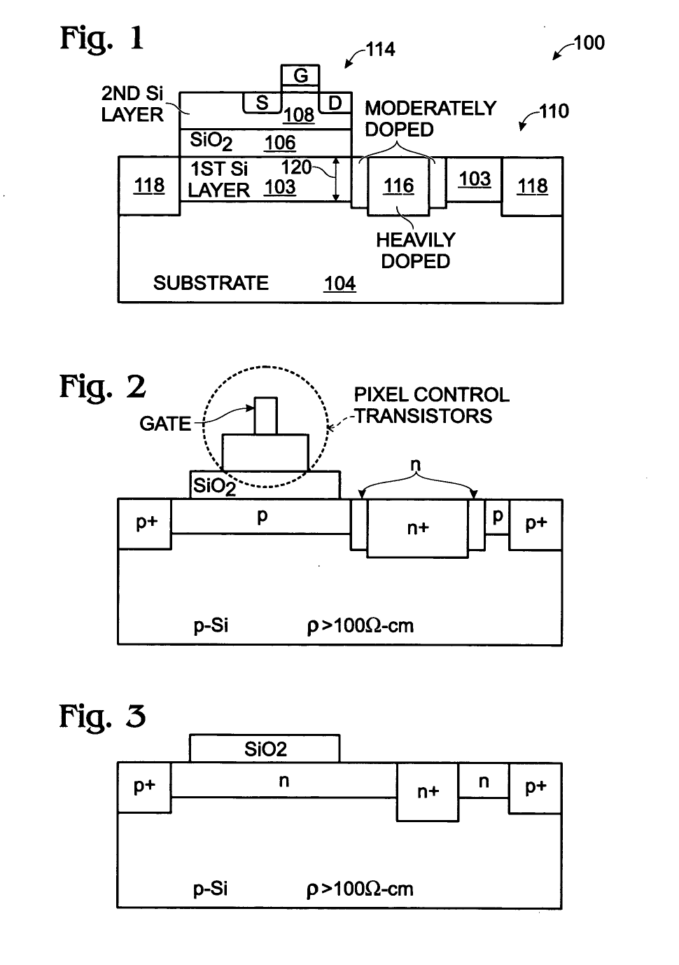

FIG. 1 is a partial cross-sectional view of a near infrared (NIR) active pixel sensor array on a silicon-on-insulator (SOI) substrate. The sensor array 100 comprises a SOI wafer 102, which includes a high resistance doped silicon (Si) substrate 104, a first Si layer 103, a silicon oxide layer 106 overlying the first Si layer 103, and a second Si layer 108 overlying the silicon oxide layer 106. A diode 110 with a p-n junction is formed underlying the silicon oxide layer 106. Shown are a diode electrode 116 and an opposite polarity electrode 118.

A thin-film transistor (TFT) 114 is formed in the first Si layer 108 and electrical interconnects (not shown) are formed between the TFT 114 and the diode 110. Although only a single TFT 114 is shown, a conventional sensor array design typically forms at least three TFTs in the first Si layer, as explained in more detail below (see FIG. 13). The Si substrate 104 can be either n-type or p-type doped, and typically has a resistance of greater than about 100 ohm-cm.

FIG. 2 is a partial cross-sectional view of a NIR active pixel sensor array on a SOI substrate with a p-doped Si substrate and a p-doped first Si layer.

FIG. 3 is a partial cross-sectional view of a NIR active pixel sensor array on a SOI substrate with a p-doped Si substrate and an n-doped first Si layer.

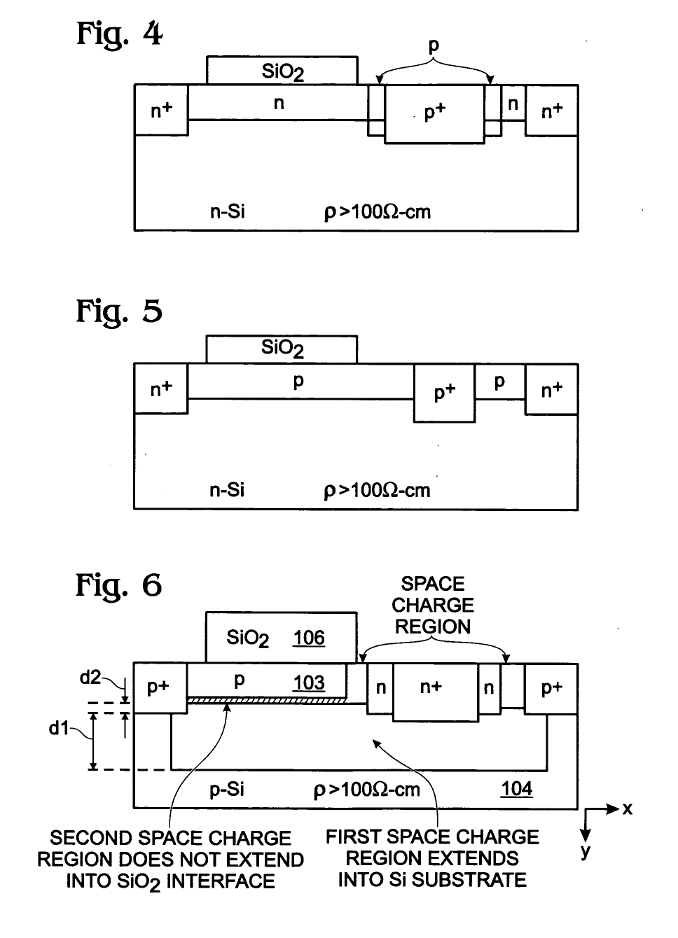

FIG. 4 is a partial cross-sectional view of a NIR active pixel sensor array on a SOI substrate with an n-doped Si substrate and an n-doped first Si layer.

FIG. 5 is a partial cross-sectional view of a NIR active pixel sensor array on a SOI substrate with an n-doped Si substrate and a p-doped first Si layer.

FIG. 6 is a partial cross-sectional view of a NIR active pixel sensor array of FIG. 2 depicting space charge regions. The equation for space charge, or depletion depth is as follows:

$$W = \sqrt{\frac{2 {ɛ}_{S}}{q} ( \frac{{N}_{A} + {N}_{D}}{{N}_{A} {N}_{D}} ) ( {V}_{bi} \pm V )}$$

W: space charge depth (width);

es: dielectric constant of the semiconductor;

q: electron charge;

NA: acceptor (p-type) dopant density;

ND: donor (n-type) dopant density;

Vbi: build in voltage;

V: applied voltage, use (+) for reverse bias and (−) for forward bias.

Generally, W increases with an increase in reverse bias. When a bias is applied with respect to the n+ and p+ contacts, the device can be seen as two diodes, performing as if they are parallel connected. Because of the relatively high dopant concentration (1×10¹⁶ to 1×10¹⁸ cm⁻³) in the first Si layer 103, the second space charge region (shown as hatched) does not extend to the Si/SiO2 interface, and the interface defect generated leakage current is minimal. On the other hand, the dopant density minimizes the occurrence of trap-assisted tunneling current, which is the reverse bias pn junction current, or the dark current for this pn junction.

The first space charge region is associated with the pin diode in the body. The Si substrate is intrinsic (“i”) with a low dopant concentration. The space charge depth is large in this diode because of the low dopant concentration in the Si substrate. Photons are absorbed in this “i” region, and generate electron and hole pairs. The electron flow to n+ cathode, and hole flow to p+ anode, generates external photo current. The depth of the space charge region in the y-axis directions increases with a large reverse bias voltage.

With a reverse bias of 2V, the first space charge region has a depth d1, and the second space charge region has a depth d2. When the reverse bias is increased to 5 V, d1 and d2 both increase. The first space charge region depth d1 increases towards the bottom of the page, while d2 increases towards the top of the page. Typically, the voltage applied to such a diode is in the range of about 2 to 5 volts. At 2 V, the first space charge region depth is at least 2 um, and the device is able to support NIR applications. At 5 V, the second space charge region depth is still less that the thickness of the first Si layer (see FIG. 1, reference designator 120).

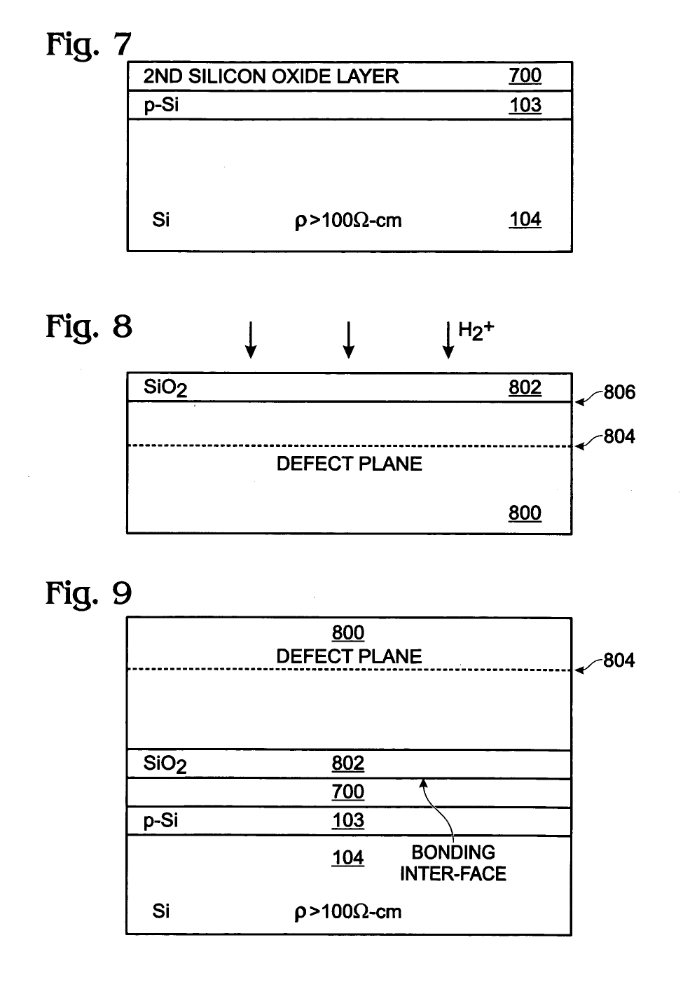

FIGS. 7 through 10 are partial cross-sectional views showing steps in the fabrication of the NIR active pixel sensor array of FIG. 1. In FIG. 7, a Si handling wafer with the resistivity higher than 100 ohm-cm is provided. The PN diode is fabricated in the handling wafer. The Si wafer can be either p-type doped or n-type doped. Here a p-type doped substrate is shown. A blanket B-ion implantation is performed on the Si handling wafer. The B concentration is between 1×10¹⁶ cm⁻³ to 1×10¹⁸ cm⁻³, resulting in the first Si substrate 104 and the first Si layer 103 having a thickness 120 in the range of about 50 nm to 300 nm. Optionally as shown, the first Si layer surface may be oxidized to form a second silicon oxide layer 700. If performed, the thermal oxidation step occurs prior to the B-ion implantation.

In FIG. 8, a donor wafer is prepared. Shown is a p-type Si wafer 800. Thermal oxide 802 is grown to a thickness of about 20 nm to 500 nm. Ions of H2+, H+, Ar+, He+ or Ne+ are implanted into the Si wafer to generate a defect plane 804. The defect plane 804 is located about 0.1 μm (micrometer) to 1 μm below the Si/SiO2 interface 806. The dose density is between 5×10¹⁵ to 5×10¹⁶ cm⁻².

In FIG. 9, the donor and handle wafers are bonded. The bonding occurs spontaneously when the wafers are brought close to each other. The bonder wafer is cured to improve the bonding energy.

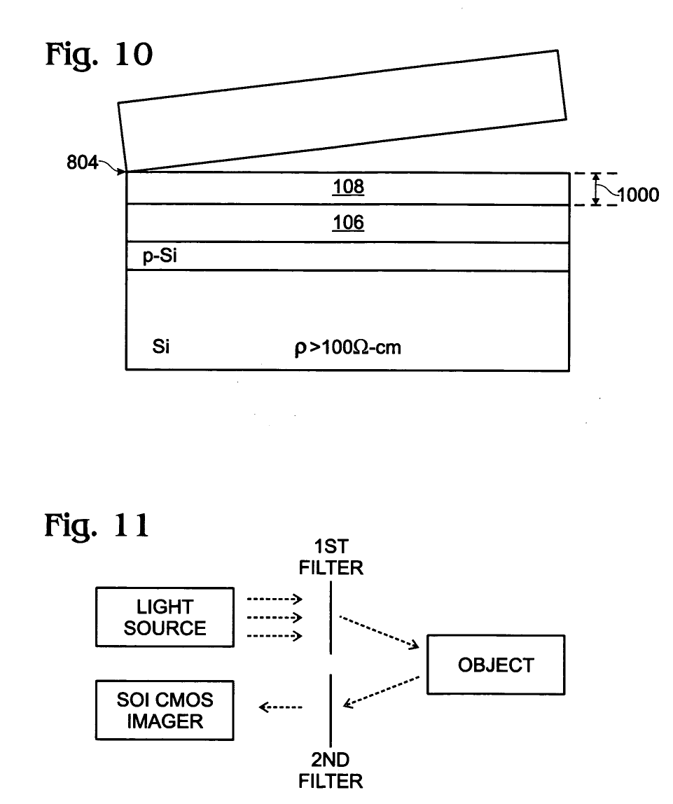

In FIG. 10, the bonded wafer pair is split along the defect layer by annealing in a furnace with temperature between about 350° C. to about 800° C. The second silicon oxide layer is merged into the first silicon oxide layer 106, and the resultant SOI wafer is annealed to improve the bonding energy. The surface of the second Si layer 108 receives a chemical-mechanical polish (CMP), dry etch, and wet cleaning to condition the wafer surface layer for device fabrication. The second Si layer thickness 1000 is between about 20 nm to about 300 nm, after all the surface preparation is completed.

FIG. 11 is a schematic block diagram showing an application for the NIR active pixel sensor array. One potential application of this SOI CMOS NIR imager is in car safety application. The IR source can be IR LED, IR Laser, or a conventional halogen bulb with a filter to allow only IR to penetrate. The IR source is used as in the high beam condition and it avoids blinding the driver coming from the opposite direction. The reflected signal passes a second filter and is received by the SOI CMOS imager. The purpose of the second filter is to prevent any visible light from reaching the imager that may blind the imager. The driver can then view the NIR image on a monitor, such as an LCD display, or an image projected onto the windshield. Safety is enhanced because the driver can see better, without blinding the driver of the oncoming car.

Another potential application of this SOI CMOS NIR imager is for security applications, for example, in finger vein recognition, palm vein reading, or retina reading. An IR LED is used as light source, and the IR light is absorbed by the blood vessel. The reflection of IR light is sensed by the SOI CMOS Imager, so that the vein shape can be detected by the imager.

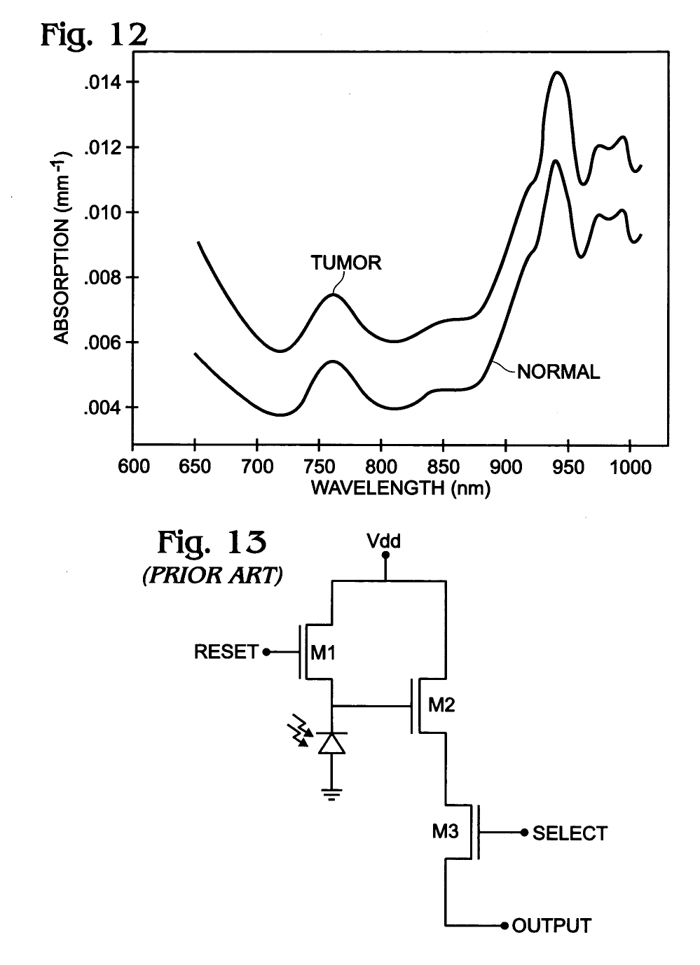

FIG. 12 is a graph depicting the difference in absorption spectra between normal and cancerous tissue. The graph suggests a SOI CMOS NIR imager application for the noninvasive identification of tumors. Different kinds of tissue absorb NIR light differently. This difference in absorption can be measured. Furthermore, NIR light from a source like an LED can penetrate 10-15 mm below the skin. NIR imaging and spectroscopy can be used to image and analyze tumors, characterize suspicious lesions in mammograms without surgery, detect the effects of traumatic injury and progression to shock well before it occurs, or monitor the effects of tumor chemotherapies during treatment.

FIG. 13 is a schematic diagram of a conventional active pixel circuit (prior art). If this circuit is fabricated in accordance with the above-described NIR active pixel sensor array, the photodiode is formed in the Si substrate. The transistors M1, M2 and M3 are all fabricated on the top Si layer (see FIG. 1).

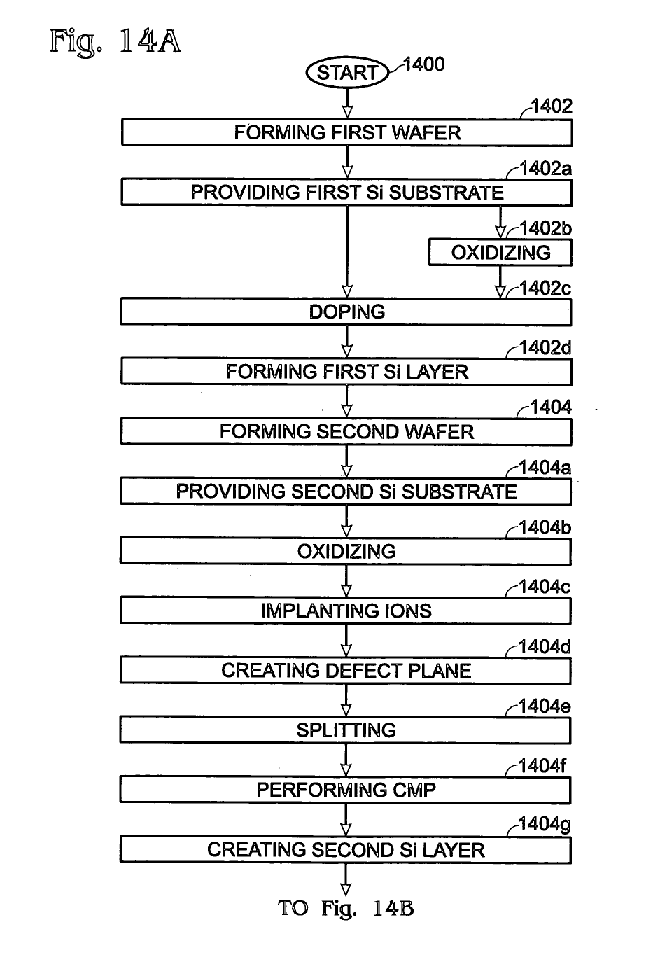

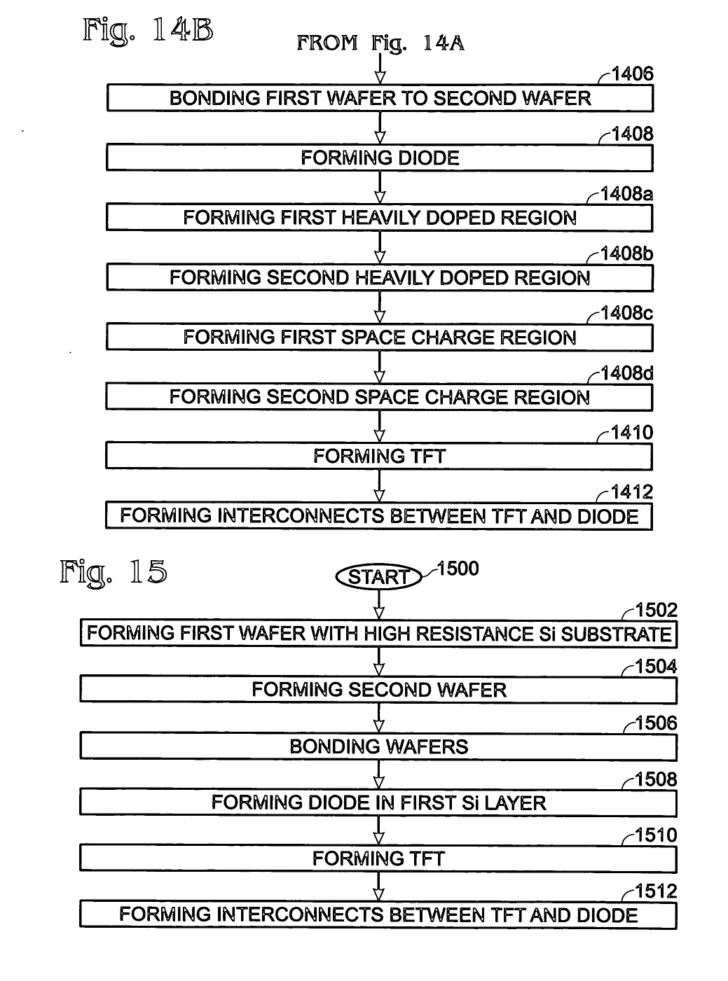

FIGS. 14A and 14B are flowcharts illustrating a method for forming a NIR active pixel sensor array on a SOI substrate. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1400.

Step 1402 forms a first wafer comprising a high resistance first Si substrate and a moderately doped first Si layer. Step 1404 forms a second wafer comprising a first silicon oxide layer and a second Si layer. Step 1406 bonds the first wafer to the second wafer, forming a SOI substrate. Step 1408 forms a diode with a p-n junction space charge region extending into the first Si substrate. Step 1410 forms a thin-film transistor (TFT) in the second Si layer. Step 1412 forms interconnects between the TFT and the diode.

In one aspect, forming the first wafer in Step 1402 includes substeps. Step 1402a provides the high resistivity first Si substrate. Typically, the first Si substrate has a resistivity of greater than about 100 ohm-cm. Step 1402c dopes the first Si substrate. Step 1402d, in response to the doping, forms the first Si layer overlying the first Si substrate. For example, the first Si layer may have a dopant concentration in the range of about 1×10¹⁶ to about 5×10¹⁸ cm⁻³, and a thickness in the range of about 50 to 300 nm.

Optionally, Step 1402b forms a second silicon oxide layer overlying the first Si substrate, prior to doping the first Si substrate in Step 1402c. Then, bonding the first wafer to the second wafer in Step 1406 includes bonding the second silicon oxide layer of the first wafer to the first silicon oxide layer of the second wafer.

In another aspect, forming the second wafer in Step 1404 includes substeps. Step 1404a provides a second Si substrate, which may be undoped, lightly doped, or moderately doped Si. Step 1404b oxidizes a surface of the second Si substrate, forming the first silicon oxide layer. Step 1404c implants ions into the second Si substrate. For example, the ions may be H2+, H+, Ar+, He+, and Ne+, implanted with a dosing density in the range of about 5×10¹⁵ to about 5×10¹⁶ cm⁻². Step 1404d creates a defect plane in the second Si substrate. For example, the defect plane may be about 0.1 to 1 micrometers below the first silicon oxide interface to the second Si substrate.

Step 1404e splits the bonded first and second wafers along the defect plane. For example, the bonded first and second wafers may be split by annealing at a temperature in the range of about 350 to 800° C. Step 1404f performs a CMP process along the exposed defect plane in the second Si substrate. Step 1404g creates the second Si layer thickness in the range of about 20 to 500 nm, in response to the CMP of Step 1404f.

More specifically, forming the SOI substrate in Step 1406 includes forming the first silicon oxide layer with a first sidewall and an opposing second sidewall. Then, forming the diode in Step 1408 includes substeps. Step 1408a forms a first heavily doped region in the first Si layer adjacent the silicon oxide layer first sidewall. Step 1408b forms a second heavily doped region, opposite in polarity to the first heavily doped region, in the first Si layer adjacent the silicon oxide layer second sidewall. Step 1408c forms a first space charge region between the first and second heavily doped regions, extending into the first Si substrate at a depth greater than about 2 micrometers, in response to a reverse bias voltage of about 2 volts. In another aspect, Step 1408d forms a second space charge region extending through the first Si layer at a depth less than the first Si layer thickness, without intersecting the interface between the first Si layer and the first silicon oxide layer, in response to a reverse bias of about 5 volts.

In a first aspect, Step 1402 forms a p-type doped first Si layer and a p-type doped high resistance first Si substrate. Then Step 1408 forms a n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer. Further, Step 1408 may form an n-region adjacent the n+ region, separating the n+ region from the p+ region, with a dopant concentration greater than the first Si layer dopant concentration, in the range of about 2×10¹⁶ cm⁻³ to 1×10¹⁹ cm⁻³. In one aspect, the p+ region forms a p+ perimeter in the first Si layer surrounding the n+ and n regions.

In a second aspect, Step 1402 forms a p-type doped first Si layer and an n-type doped high resistance first Si substrate. Then, Step 1408 forms an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

In a third aspect, Step 1402 forms an n-type doped first Si layer and a n-type doped high resistance first Si substrate. Then, Step 1408 forms an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

In a fourth aspect, Step 1402 forms a p-type doped first Si layer and a p-type doped high resistance first Si substrate. Then, Step 1408 forms an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

FIG. 15 is a flowchart illustrating an alternate aspect to the method for forming a NIR active pixel sensor array on a SOI substrate. The method starts at Step 1500. Step 1502 forms a first wafer comprising a first Si substrate having a resistivity greater than about 100 ohm-cm, and a first Si layer with a dopant concentration in the range of about 1×10¹⁶ to about 5×10¹⁸ cm⁻³. Step 1504 forms a second wafer comprising a first silicon oxide layer and a second Si layer. Step 1506 bonds the first wafer to the second wafer, forming a SOI substrate. Step 1508 forms a diode with a first region, with a dopant concentration in the range of about 1×10¹⁹ cm⁻³ to 5×10²⁰ cm⁻³, and second region having a opposite polarity doping than the first region, with a dopant concentration in the range of about 1×10¹⁹ cm⁻³ to 5×10²⁰ cm⁻³, in the first Si layer. Step 1510 forms a TFT in the second Si layer, and Step 1512 forms interconnects between the TFT and the diode.

A near infrared (NIR) active pixel sensor array on a silicon-on-insulator (SOI) substrate has been provided, along with a corresponding fabrication process. Examples of specific details and device structures have been given to illustrate the invention, however, the invention is not limited to merely these examples. Other variations and embodiments of the invention will occur to those skilled in the art.

We claim:

1. A method for forming a near infrared (NIR) active pixel sensor array on a silicon-on-insulator (SOI) substrate, the method comprising:
forming a first wafer comprising a high resistance first Si substrate and a moderately doped first Si layer;
forming a second wafer comprising a first silicon oxide layer and a second Si layer;
bonding the first wafer to the second wafer, forming a SOI substrate;
forming a diode with a p-n junction space charge region extending into the first Si substrate;
forming a thin-film transistor (TFT) in the second Si layer; and,
forming interconnects between the TFT and the diode.

2. The method of claim 1 wherein forming the first wafer includes:
providing the high resistivity first Si substrate;
doping the first Si substrate; and,
in response to the doping, forming the first Si layer overlying the first Si substrate.

3. The method of claim 2 wherein forming the first Si layer includes forming the first Si layer with a dopant concentration in the range of about 1×10¹⁶ to about 5×10¹⁸ cm⁻³.

4. The method of claim 2 wherein forming the first Si layer includes forming the first Si layer with a thickness in the range of about 50 to 300 nanometers (nm).

5. The method of claim 2 wherein forming the first wafer includes forming a second silicon oxide layer overlying the first Si substrate prior to doping the first Si substrate; and,
wherein bonding the first wafer to the second wafer includes bonding the second silicon oxide layer of the first wafer to the first silicon oxide layer of the second wafer.

6. The method of claim 1 wherein forming the second wafer includes:
providing a second Si substrate;
oxidizing a surface of the second Si substrate, forming the first silicon oxide layer;
implanting ions into the second Si substrate;
creating a defect plane in the second Si substrate; and,
splitting the bonded first and second wafers along the defect plane.

7. The method of claim 6 wherein providing the second Si substrate includes providing a second Si substrate selected from the group consisting of undoped, lightly doped, and moderately doped Si.

8. The method of claim 6 wherein implanting ions into the second Si substrate includes:
implanting ions selected from the group consisting of H₂+, H+, Ar+, He+, and Ne+; and,
implanting ions with a dosing density in the range of about 5×10¹⁵ to about 5×10¹⁶ cm⁻².

9. The method of claim 6 wherein creating the defect plane includes creating the defect plane about 0.1 to 1 micrometers below the first silicon oxide interface to the second Si substrate.

10. The method of claim 6 wherein splitting the bonded first and second wafers includes annealing at a temperature in the range of about 350 to 800° C.; and,
the method further comprising:
performing a chemical-mechanical polish (CMP) process along the exposed defect plane in the second Si substrate;
in response to the CMP, creating the second Si layer thickness in the range of about 20 to 500 nm.

11. The method of claim 1 wherein the first Si substrate has a resistivity of greater than about 100 ohm-cm.

12. The method of claim 1 wherein forming the SOI substrate includes forming the first silicon oxide layer with a first sidewall and an opposing second sidewall;
wherein forming the diode includes:
forming a first heavily doped region in the first Si layer adjacent the silicon oxide layer first sidewall;
forming a second heavily doped region, opposite in polarity to the first heavily doped region, in the first Si layer adjacent the silicon oxide layer second sidewall;
forming a first space charge region between the first and second heavily doped regions, extending into the first Si substrate at a depth greater than about 2 micrometers, in response to a reverse bias voltage of about 2 volts.

13. The method of claim 12 wherein forming the diode includes forming a second space charge region extending through the first Si layer at a depth less than the first Si layer thickness, without intersecting the interface between the first Si layer and the first silicon oxide layer, in response to a reverse bias of about 5 volts.

14. The method of claim 1 wherein forming the first wafer includes forming a p-type doped first Si layer and a p-type doped high resistance first Si substrate; and,
wherein forming the diode includes forming an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

15. The method of claim 14 wherein forming the diode includes forming an n-region adjacent the n+ region, separating the n+region from the p+ region, with a dopant concentration greater than the first Si layer dopant concentration, in the range of about 2×10¹⁶ cm⁻³ to 1×10¹⁹ cm⁻³.

16. The method of claim 15 wherein forming the p+ region includes forming a p+ perimeter in the first Si layer surrounding the n+ and n regions.

17. The method of claim 1 wherein forming the first wafer includes forming a p-type doped first Si layer and an n-type doped high resistance first Si substrate; and,
wherein forming the diode includes forming an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

18. The method of claim 1 wherein forming the first wafer includes forming an n-type doped first Si layer and an n-type doped high resistance first Si substrate; and,
wherein forming the diode includes forming an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

19. The method of claim 1 wherein forming the first wafer includes forming a p-type doped first Si layer and a p-type doped high resistance first Si substrate; and,
wherein forming the diode includes forming an n+ region, with a dopant concentration in the range of about 1×10¹⁹ cm⁻³ to 5×10²⁰ cm⁻³ and a p+ region, with a dopant concentration in the range of about 1×10¹⁹ cm⁻³ to 5×10²⁰ cm⁻³, in the first Si layer.

20. A method for forming a near infrared (NIR) active pixel sensor array on a silicon-on-insulator (SOI) substrate, the method comprising:
forming a first wafer comprising a first Si substrate having a resistivity greater than about 100 ohm-cm, and a first Si layer with a dopant concentration in the range of about 1×10¹⁶ to about 5×10¹⁸ cm⁻³;
forming a second wafer comprising a first silicon oxide layer and a second Si layer;
bonding the first wafer to the second wafer, forming a SOI substrate;
forming a diode with a first region, having a dopant concentration in the range of about 1×10¹⁹ cm⁻³ to 5×10²⁰ cm⁻³, and a second region having an opposite polarity doping than the first region, with a dopant concentration in the range of about 1×10¹⁹ cm⁻³ to 5×10²⁰ cm⁻³, in the first Si layer;
forming a thin-film transistor (TFT) in the second Si layer; and,
forming interconnects between the TFT and the diode.
